(19) United States
(12) Patent Application Publication
(10) Pub. No.: US 2023/0413422 A1
(43) Pub. Date: Dec. 21, 2023

(54) 3D GLASS MODULES

(71) Applicant: ELECTRONIC DESIGN & DEVELOPMENT, CORP., Tucson, AZ (US)

(72) Inventor: Sergio E. Cardona, Jr., Tucson, AZ (US)

(21) Appl. No.: 18/337,725

(22) Filed: Jun. 20, 2023

Related U.S. Application Data
(60) Provisional application No. 63/353,720, filed on Jun. 20, 2022.

(51) Int. Cl. H05K 1/02; H05K 3/34; H05K 1/03

(52) U.S. Cl. CPC H05K 1/024; H05K 3/341; H05K 1/0306; H05K 2201/015; H05K 2201/10068; H05K 2201/10015; H05K 2201/1003; H05K 2201/10098; H05K 2203/041

(57) ABSTRACT

A hermetic glass module for wireless communication. In some embodiments, the module may comprise a plurality of glass layers comprising a first layer having capacitors, inductors, and resonators, a second layer comprising capacitors, inductors, diplexers, and waveguides, a third layer comprising microchips, and capacitors, and a fourth layer comprising a glass cover layer, and antennas disposed within the glass cover layer. The plurality of glass layers may each be separated by a substrate of a plurality of substrates and are connected by a redistribution layer (RDL) of a plurality of RDLs.

### CROSS-REFERENCES TO RELATED APPLICATIONS

This application is a non-provisional and claims benefit of U.S. Provisional Patent Application No. 63/353,720 filed Jun. 20, 2022, the specification of which is incorporated herein in its entirety by reference.

### BACKGROUND OF THE INVENTION

A multilayer circuit board can have a multitude of uses, including as a transceiver for radiofrequency and wireless communication, wireless telecom (5G and beyond), space & satcom, medical devices, and radar. However, prior printed circuit board (PCB) modules suffer from issues with use specificity, board complexity, size, and higher-level integration. Thus, there exists a present need for a multilayer circuit board that is capable of reusable functionality, reduced board complexity, minimized size, and system-on-a-chip integration.

### FIELD OF THE INVENTION

The present invention is directed to a scalable and cost-efficient multilayer glass PCB module for wireless communication purposes.

### BRIEF SUMMARY OF THE INVENTION

It is an objective of the present invention to provide devices that allow for a scalable and cost-efficient multilayer glass PCB module for wireless communication purposes, as specified in the independent claims. Embodiments of the invention are given in the dependent claims. Embodiments of the present invention can be freely combined with each other if they are not mutually exclusive.

The present invention features a hermetic glass module for wireless communication. In some embodiments, the module may comprise a plurality of glass layers. The plurality of glass layers may comprise a first layer comprising a first set of one or more capacitors, a first set of one or more inductors, and a set of one or more resonators. The plurality of glass layers may further comprise a second layer comprising a second set of one or more capacitors, a second set of one or more inductors, a set of one or more diplexers, and a set of one or more waveguides. The plurality of glass layers may further comprise a third layer comprising a set of one or more microchips, and a third set of one or more capacitors. The plurality of glass layers may further comprise a fourth layer comprising a glass cover layer, and one or more antennas disposed within the glass cover layer. The plurality of glass layers may each be separated by a substrate of a plurality of substrates and are connected by a redistribution layer (RDL) of a plurality of RDLs.

One of the unique and inventive technical features of the present invention is the implementation of redistribution layers between substrates of the 3D glass module. Without wishing to limit the invention to any theory or mechanism, it is believed that the technical feature of the present invention advantageously provides for increased modularity and scalability. None of the presently known prior references or work has the unique inventive technical feature of the present invention.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1 shows a schematic diagram of the three-dimensional glass module of the present invention.

FIG. 2 shows a flow chart diagram for fabricating the three-dimensional glass module of the present invention.

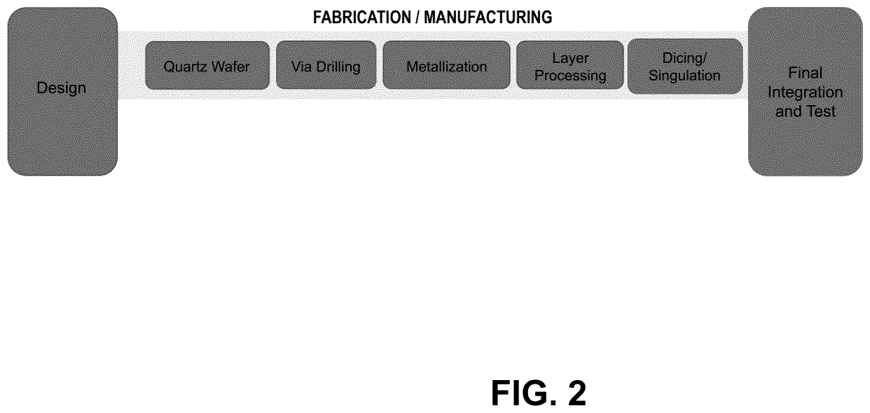

FIG. 3 shows a diagram of the scalability of the three-dimensional glass module of the present invention with a single module being incorporated into an array of multiple modules.

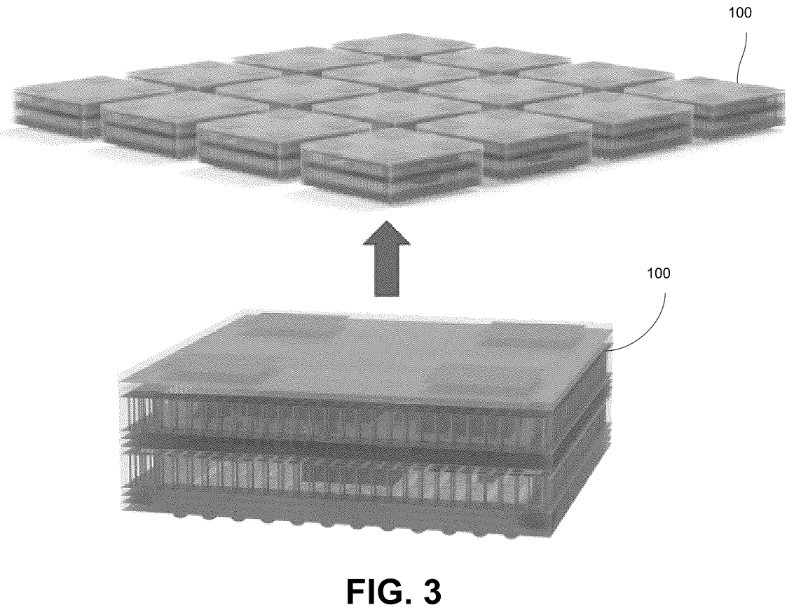

### DETAILED DESCRIPTION OF THE INVENTION

Following is a list of elements corresponding to a particular element referred to herein:
100 module
110 first layer
111 first substrate
112 first glass wall
113 first gap
114 first set of capacitors
115 first set of inductors
120 second layer
121 second substrate
122 BAW resonator
123 SAW resonator
124 glass layer
125 second set of capacitors
126 second set of inductors
127 diplexers
128 waveguides
130 third layer
131 third substrate
132 second glass wall
133 second gap
134 microchips
135 third set of capacitors
140 fourth layer
141 fourth substrate
142 glass cover layer
143 antennas
200 solder balls

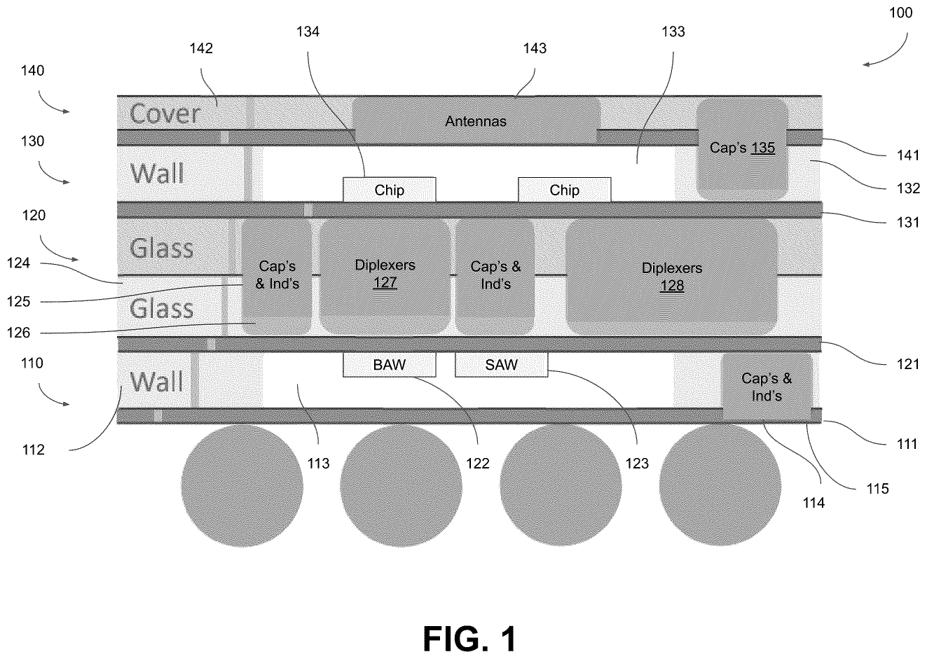

Referring now to FIG. 1, the present invention features a multilayer hermetic glass module (100) for wireless communication. In some embodiments, the module (100) may comprise a plurality of glass layers each separated by a substrate of a plurality of substrates and connected by a redistribution layer (RDL) of a plurality of RDLs. One or more electronic components may be disposed within the plurality of glass layers. In some embodiments, the one or more electronic components may be selected from a group consisting of capacitors (114, 125, 135), inductors (115, 126), resonators (122, 123), microchips (134), antennas (143), diplexers (127), and waveguides (128).

In some embodiments, the resonators (122, 123) may comprise a bulk acoustic wave (BAW) resonator (122), a surface acoustic wave (SAW) resonator (123), or a combination thereof. In some embodiments, the antennas (143) comprise a Wifi antenna, a long-range (LoRa) antenna, a wide-area network (WAN) antenna, a low-power wide-area network (LPWAN) antenna, or a combination thereof. In some embodiments, the capacitors may comprise fixed capacitors, variable capacitors, or a combination thereof. In some embodiments, the inductors may comprise air-core inductors, ferromagnetic-core inductors, variable inductors, chokes, or a combination thereof. In some embodiments, the microchips (134) may comprise logic chips, memory chips, application-specific integrated chips (ASICs), or a combination thereof. In some embodiments, each substrate of the plurality of substrates may comprise copper, alumina, Polytetrafluoroethylene (PTFE), Kapton, or a combination thereof. In some embodiments, the module (100) may comprise one or more solder balls (200) disposed on a bottom surface of the first substrate (110).

According to other embodiments, the present invention features a hermetic glass module (100) for wireless communication. In some embodiments, the module (100) may comprise a plurality of glass layers. The plurality of glass layers may comprise a first layer (110) comprising a first set of one or more capacitors (114), a first set of one or more inductors (115), and a set of one or more resonators (122, 123). The plurality of glass layers may further comprise a second layer (120) comprising a second set of one or more capacitors (125), a second set of one or more inductors (126), a set of one or more diplexers (127), and a set of one or more waveguides (128). The plurality of glass layers may further comprise a third layer (130) comprising a set of one or more microchips (134), and a third set of one or more capacitors (135). The plurality of glass layers may further comprise a fourth layer (140) comprising a glass cover layer (142), and one or more antennas (143) disposed within the glass cover layer (142). The plurality of glass layers may each be separated by a substrate of a plurality of substrates and are connected by a redistribution layer (RDL) of a plurality of RDLs.

According to some other embodiments, the present invention features a hermetic glass module (100) for wireless communication. In some embodiments, the module (100) may further comprise a first layer (110) comprising a first substrate (111), a first glass wall (112) disposed around a perimeter of the substrate, the first glass wall (112) encompassing a first gap (113), a first set of one or more capacitors (114) disposed within the first glass wall (112), and a first set of one or more inductors (115) disposed within the glass wall. In some embodiments, the module may further comprise a second layer (120) coupled to the first layer (110) by a redistribution layer (RDL). The second layer (120) may comprise a second substrate (121) disposed on top of the glass wall of the first layer (110), a bulk acoustic wave (BAW) resonator (122) disposed on a bottom surface of the second substrate (121) such that the BAW resonator (122) is disposed in the first gap (113), a surface acoustic wave (SAW) resonator (123) disposed on a bottom surface of the second substrate (121) such that the SAW resonator (123) is disposed in the first gap (113), and a glass layer (124) disposed on top of the second substrate (121. The glass layer (124) may be divided horizontally into a first sublayer and a second sublayer. The second layer (120) may further comprise a second set of one or more capacitors (125) disposed within the glass layer (124), a second set of one or more inductors (126) disposed within the glass layer (124), one or more diplexers (127) disposed within the glass layer (124), and one or more waveguides (128) disposed within the glass layer (124).

The module (100) may further comprise a third layer (130) coupled to the second layer (120) by a RDL. The third layer may comprise a third substrate (131) disposed on top of the glass layer (124), a second glass wall (132) disposed around a perimeter of the third substrate (131), the second glass wall (132) enclosing a second gap (133), one or more microchips (134) disposed on a top surface of the third substrate (131) such that the one or more microchips (134) are disposed within the second gap (133), and a third set of one or more capacitors (135) disposed within the second glass wall (132). The module (100) may further comprise a fourth layer (140) coupled to the third layer (130) by a RDL. The fourth layer (140) may comprise a fourth substrate (141) disposed on top of the second glass wall (132), a glass cover layer (142) disposed on top of the fourth substrate (141), and one or more antennas (143) disposed within the glass cover layer (142). In some embodiments, the module (100) may further comprise one or more solder balls (200) disposed on a bottom surface of the first substrate (110).

In some embodiments, a redistribution layer (RDL) may comprise a layer of wiring interconnects that are fabricated onto a substrate layer to allow for improved bonding between substrate layers as well as a redistribution of I/O access to different parts of the chip layer. This has previously not been implemented in a multilayer hermetic glass module for wireless communication.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

The reference numbers recited in the below claims are solely for ease of examination of this patent application, and are exemplary, and are not intended in any way to limit the scope of the claims to the particular features having the corresponding reference numbers in the drawings.

What is claimed is:

1. A multilayer hermetic glass module (100) for wireless communication, the module (100) comprising a plurality of glass layers each separated by a substrate of a plurality of substrates and connected by a redistribution layer (RDL) of a plurality of RDLs, wherein one or more electronic components are disposed within the plurality of glass layers.

2. The module (100) of claim 1, wherein the one or more electronic components are selected from a group consisting of capacitors (114, 125, 135), inductors (115, 126), resonators (122, 123), microchips (134), antennas (143), diplexers (127), and waveguides (128).

3. The module (100) of claim 2, wherein the resonators (122, 123) comprise a bulk acoustic wave (BAW) resonator (122), a surface acoustic wave (SAW) resonator (123), or a combination thereof.

4. The module (100) of claim 1, wherein the antennas (143) comprise a Wifi antenna, a long-range (LoRa) antenna, a wide-area network (WAN) antenna, a low-power wide-area network (LPWAN) antenna, or a combination thereof.

5. The module (100) of claim 1, wherein the capacitors comprise fixed capacitors, variable capacitors, or a combination thereof.

6. The module (100) of claim 1, wherein the inductors comprise air-core inductors, ferromagnetic-core inductors, variable inductors, chokes, or a combination thereof.

7. The module (100) of claim 1, wherein the microchips (134) comprise logic chips, memory chips, application-specific integrated chips (ASICs), or a combination thereof.

8. The module (100) of claim 1, wherein each substrate of the plurality of substrates comprises copper, alumina, Polytetrafluoroethylene (PTFE), Kapton, or a combination thereof.

9. The module (100) of claim 1 further comprising one or more solder balls (200) disposed on a bottom surface of the first substrate (110).

10. A hermetic glass module (100) for wireless communication, the module (100) comprising a plurality of glass layers comprising:
a. a first layer (110) comprising:
i. a first set of one or more capacitors (114);
ii. a first set of one or more inductors (115); and
iii. a set of one or more resonators (122, 123);
b. a second layer (120) comprising:
i. a second set of one or more capacitors (125);
ii. a second set of one or more inductors (126);
iii. a set of one or more diplexers (127); and
iv. a set of one or more waveguides (128);
c. a third layer (130) comprising:
i. a set of one or more microchips (134); and
ii. a third set of one or more capacitors (135); and
d. a fourth layer (140) comprising:
i. a glass cover layer (142); and
ii. one or more antennas (143) disposed within the glass cover layer (142);
wherein the plurality of glass layers are each separated by a substrate of a plurality of substrates and are connected by a redistribution layer (RDL) of a plurality of RDLs.

11. The module (100) of claim 10, wherein the set of one or more resonators (122, 123) comprises a bulk acoustic wave (BAW) resonator (122), a surface acoustic wave (SAW) resonator (123), or a combination thereof.

12. The module (100) of claim 10, wherein the one or more antennas (143) comprise a Wifi antenna, a long-range (LoRa) antenna, a wide-area network (WAN) antenna, a low-power wide-area network (LPWAN) antenna, or a combination thereof.

13. The module (100) of claim 10, wherein the first set of one or more capacitors (114), the second set of one or more capacitors (125), and the third set of one or more capacitors (135) comprising fixed capacitors, variable capacitors, or a combination thereof.

14. The module (100) of claim 10, wherein the first set of one or more inductors (115) and the second set of one or more inductors (126) comprise air-core inductors, ferromagnetic-core inductors, variable inductors, chokes, or a combination thereof.

15. The module (100) of claim 10, wherein the set of one or more microchips (134) comprise logic chips, memory chips, application-specific integrated chips (ASICs), or a combination thereof.

16. The module (100) of claim 10, wherein each substrate of the plurality of substrates comprises copper, alumina, Polytetrafluoroethylene (PTFE), Kapton, or a combination thereof.

17. The module (100) of claim 10 further comprising one or more solder balls (200) disposed on a bottom surface of the first substrate (110).

18. A hermetic glass module (100) for wireless communication, the module (100) comprising:
a. a first layer (110) comprising:
i. a first substrate (111);
ii. a first glass wall (112) disposed around a perimeter of the substrate, the first glass wall (112) encompassing a first gap (113);
iii. a first set of one or more capacitors (114) disposed within the first glass wall (112); and
iv. a first set of one or more inductors (115) disposed within the glass wall;
b. a second layer (120) coupled to the first layer (110) by a redistribution layer (RDL), comprising:
i. a second substrate (121) disposed on top of the glass wall of the first layer (110);
ii. a bulk acoustic wave (BAW) resonator (122) disposed on a bottom surface of the second substrate (121) such that the BAW resonator (122) is disposed in the first gap (113);
iii. a surface acoustic wave (SAW) resonator (123) disposed on a bottom surface of the second substrate (121) such that the SAW resonator (123) is disposed in the first gap (113);
iv. a glass layer (124) disposed on top of the second substrate (121), wherein the glass layer (124) is divided horizontally into a first sublayer and a second sublayer;
v. a second set of one or more capacitors (125) disposed within the glass layer (124);
vi. a second set of one or more inductors (126) disposed within the glass layer (124);
vii. one or more diplexers (127) disposed within the glass layer (124); and
viii. one or more waveguides (128) disposed within the glass layer (124);
c. a third layer (130) coupled to the second layer (120) by a RDL, comprising:
i. a third substrate (131) disposed on top of the glass layer (124);
ii. a second glass wall (132) disposed around a perimeter of the third substrate (131), the second glass wall (132) enclosing a second gap (133);
iii. one or more microchips (134) disposed on a top surface of the third substrate (131) such that the one or more microchips (134) are disposed within the second gap (133); and
iv. a third set of one or more capacitors (135) disposed within the second glass wall (132); and
d. a fourth layer (140) coupled to the third layer (130) by a RDL, comprising:
i. a fourth substrate (141) disposed on top of the second glass wall (132);
ii. a glass cover layer (142) disposed on top of the fourth substrate (141); and
iii. one or more antennas (143) disposed within the glass cover layer (142).

19. The module (100) of claim 18 further comprising one or more solder balls (200) disposed on a bottom surface of the first substrate (110).
